(19) United States
(12) Patent Application Publication
(10) Pub. No.: US 2025/0308840 A1
(43) Pub. Date: Oct. 2, 2025

(54) SAMPLE PREPARATION WITH NON-UNIFORM DOSE

(71) Applicant: FEI COMPANY, Hillsboro, OR (US)

(72) Inventors: Jaroslav Stárek, Krelov-Bruchotín (CZ); Tomáš Onderlicka, Brno (CZ); Jamie Gravell, Hillsboro, OR (US); Jaroslav Maniš, Tucapy (CZ)

(73) Assignee: FEI COMPANY, Hillsboro, OR (US)

(21) Appl. No.: 18/622,554

(22) Filed: Mar. 29, 2024

(51) Int. Cl. H01J 37/305; G01N 1/32; H01J 37/32

(52) U.S. Cl. CPC H01J 37/3056; G01N 1/32; H01J 37/32449

(57) ABSTRACT

Variable dosage ion beam milling techniques for sample preparation are disclosed. A charged particle microscope system can be configured to remove a first layer of material from a sample to reduce a thickness of a first portion of the sample by at least directing an ion beam toward the first portion of the sample. After the first layer is removed, a second layer of material can be removed from the sample to reduce a thickness of a second portion of the sample by at least directing the ion beam toward the second portion of the sample. The ion beam can be directed toward the second portion according to a variable dose.

The present disclosure is directed to charged particle microscopy. More particularly, the present disclosure describes methods and systems for sample preparation using non-uniform ion beam dose across the surface of a sample.

### BACKGROUND

Charged particle microscopy can be used to investigate and analyze samples, for example using transmission electron microscopes (TEM). To view samples with a TEM, thin lamellae are formed from the sample including various structures and other features to be imaged with the TEM. Lamellae are thin membranes that are partially transparent to electrons and are typically between 7 nm to 25 nm in thickness. Due to the small dimensions of the lamellae, careful preparation of the lamellae is required to preserve structures in the sample for imaging.

### BRIEF SUMMARY

The techniques described herein are directed to systems and methods for preparing samples for imaging using non-uniform or variable ion beam dose. One embodiment is directed to a system, for example a dual beam charged particle microscope system. The system can include a vacuum chamber, a sample stage disposed in the vacuum chamber and configured to receive a sample in the vacuum chamber, an ion beam column configured to provide an ion beam into the vacuum chamber; and a controller including one or more processors and one or more memories storing computer-executable instructions that, when executed by the one or more processors, cause the system to preform one or more operations. The operations can include removing a first layer of material from the sample such that a thickness of a first portion of the sample is reduced. The first layer can be removed by at least directing the ion beam toward the first portion of the sample. The operations can also include removing, after the first layer is removed, a second layer of material from the sample such that a thickness of a second portion of the sample is reduced. The second portion can be included in the first portion (e.g., a sub-region of the first portion). The second layer can be removed by at least directing the ion beam toward the second portion of the sample according to a variable dose.

In several examples, the operation of removing the second layer of material from the sample can include directing the ion beam toward the second portion in a pattern. The variable dose can include repeating a sweep of the ion beam across the second portion for one or more lines of the pattern a predetermined number of times. The variable dose can include a variable dwell time of the ion beam at one or more positions of the pattern. The variable dose can also include a variable angle between the ion beam and the sample at one or more positions of the pattern. In some examples, the variable dose can vary linearly across the second portion of the sample. In other examples, the variable dose can vary non-linearly across the second portion of the sample.

In some examples, removing the first layer of material can include directing the ion beam toward the first portion at a first energy, and removing the second layer of material can include directing the ion beam toward the second portion at a second energy less than the first energy according to the variable dose. The second portion can include a region of interest.

In an example, the system can be configured to perform additional operations including rotating the sample stage to position a surface opposite the second portion of the sample in a path of the ion beam and removing a third layer of material from the sample such that the thickness of the second portion of the sample is further reduced. The third layer can be removed by at least directing the ion beam toward the surface opposite the second portion at the second energy and according to the variable dose.

In an example, the thickness of the second portion can be characterized by a uniform thickness across the region of interest. The uniform thickness can have a variation of less than about 2 nm over 300 nm of height of the region of interest.

In an example, the operation of removing the second layer of material can be stopped based at least in part on comparing an image of the region of interest to an endpoint.

Another embodiment is directed to a non-transitory computer-readable medium storing instructions that, comprising instructions that, when executed by a processor of a charged particle microscopy system, cause the charged particle microscopy system to perform the operations described above.

Still another embodiment is directed toward a method that can include thinning a sample to a thickness by at least using an ion beam to remove a layer of material from a surface of the sample. The ion beam can be configured to apply a variable dose to at least a portion of the surface of the sample. The method can be performed by the charged particle microscopy system described above.

### BRIEF DESCRIPTION OF THE DRAWINGS

The foregoing aspects and many of the attendant advantages of the present disclosure will become more readily appreciated as the same become better understood by reference to the following detailed description, when taken in conjunction with the accompanying drawings.

FIG. 1 is a schematic diagram of an example dual beam system for preparing samples using non-uniform dose, according to some embodiments.

FIG. 2 is a diagram illustrating a view of a sample for preparation showing a region of interest, according to some embodiments.

FIG. 3A is a diagram illustrating the profile a sample first prepared with a uniform dose and subject to milling with a non-uniform dose, according to some embodiments.

FIG. 3B is a diagram illustrating a profile of a sample subject to milling with a non-uniform dose, according to some embodiments.

FIG. 4 is a diagram illustrating a view of a sample subject to milling with a non-uniform dose, according to some embodiments.

FIG. 5A is a diagram illustrating a view of a cutface of a sample prepared with a uniform dose, according to some embodiments.

FIG. 5B is a diagram illustrating a view of a cutface of a sample prepared with a non-uniform dose, according to some embodiments.

FIG. 6A is a diagram illustrating a profile view of a sample prepared with a uniform dose, according to some embodiments.

FIG. 6B is a diagram illustrating a profile view of a sample prepared with a non-uniform dose, according to some embodiments.

FIG. 7 is a flow diagram of an example process for operating a dual beam charged particle microscope system to prepare a sample using a non-uniform dose, according to some embodiments.

In the drawings, like reference numerals refer to like parts throughout the various views unless otherwise specified. Not all instances of an element are necessarily labeled to reduce clutter in the drawings where appropriate. The drawings are not necessarily to scale, emphasis instead being placed upon illustrating the principles being described.

### DETAILED DESCRIPTION

While exemplary embodiments have been illustrated and described, it will be appreciated that various changes can be made therein without departing from the spirit and scope of the disclosure.

Charged particle microscopy is used in various industries, including the semiconductor industry, to analyze micrometer and nanometer scale structures. For example, semiconductor devices can include nanometer scale transistors densely arranged within a silicon wafer. Images obtained with charged particle microscopy can be used to improve process control, evaluate the quality of fabricated devices, and improve yields. In the case of semiconductor devices, objects like field effect transistors (FETs) may be formed within the larger silicon wafer and adjacent to several other structures, including other FETs, vias, diode junctions, and the like. Because of the extremely small scale and dense packing of the elements, imaging of these elements can be improved by careful preparation of the sample.

Imaging samples with a charged particle microscope can include using a transmission electron microscope (TEM), a scanning electron microscope (SEM), a scanning TEM (STEM), or related techniques. To image samples using these techniques, a lamella is formed and removed from the larger substrate (e.g., the silicon wafer). The lamella can include the structures forming the devices (e.g., FETs). The lamella can be formed and removed using a dual beam charged particle microscope system, which typically includes a focused ion beam (FIB) and a SEM. During the lamella formation process, the FIB is used to remove material from the substrate, leaving the lamella as a portion of the remaining material, while the SEM is used for imaging to guide the FIB process. This process has become conventional in many industries, not just the semiconductor industry, and is used to image and analyze almost any type of micron or nanometer scale structure buried within a surrounding substrate.

Once a lamella has been removed from the surrounding material, additional milling with the FIB can be performed to further thin the lamella. For example, an initial lamella sample from a substrate can be formed with a thickness on the order of 1 μm. Milling the lamella in one or more steps with various ion beam energies (e.g., 30 kV, 2 kV) can reduce a portion of the initial lamella sample to thicknesses of less than 100 nm, including, for example, lamellae having thicknesses of 50 nm, 20 nm, 15 nm, and less than 10 nm. By thinning the lamella, image resolution of structures within the lamella can be improved.

In the case of semiconductor devices, the continued development of smaller scale structures that are more closely packed within their substrate has led to challenges in forming suitable lamellas for imaging purposes. Small scale structures may be arranged in several layers within the same substrate, such that structures of layers in front of or behind the structure of interest can obscure or occlude the structure of interest during imaging. For example, a lamella can include a line of transistor elements (e.g., semiconductor channel fins) spaced apart from another line of transistor elements by 50 nm. To image only one line of transistor elements, the lamella can be thinned to remove the material containing the other line of transistor elements. In some examples, the device lines can be spaced apart by 20 nm or less, so that it may be desirable to prepare lamellae having thicknesses less than 20 nm.

Depending on the structure of the devices in the sample, the region of interest (ROI) for imaging the sample may be large relative to the desired thickness of the lamella. For example, an ROI for a device line with structures that have a relatively large vertical extent can have dimensions of 2,500 nm by 400-1,000 nm, with the desired thickness within the ROI of less than 12 nm.

Thinning a lamella can include using an ion beam to remove portions of the sample from a cutface. The lamella can be reoriented 180° and the ion beam used to remove portions from the sample from another cutface opposite the first cutface. Depending on parameters of the ion beam (e.g., beam incidence angle, beam profile, beam energy, etc.), the material removed from the lamella can result in a lamella with various profiles. For example, a conventional thinning operation may thin the sample to a wedge-shaped profile having a thin region near the “base” of the lamella and a relatively thicker region near the “top.” More recent techniques include thinning to a vase-shaped lamella, where the sample has a thicker region near the top, a thin region toward the base, and then a thicker region at the base. The thin region may correspond to the ROI including the structures that are desired to be imaged. Although a vase-shaped lamella can result in very thin samples over a region of interest, with some degree of parallelism of the cutfaces, such a technique is also highly sensitive to the state of the charged particle microscopy system. For example, stability of the ion beam can limit repeatability of the sample preparation, so that samples may exhibit variance in thickness or size of the ROI. A lack of repeatability in sample processing can prevent full automation of the sample preparation.

To avoid these drawbacks when creating vase-shaped lamellae, the techniques of the present disclosure make use of a non-uniform dose of the ion beam when applied to the cutface of the sample during milling. As used herein and more fully discussed below with respect to the various figures, the term “dose” may refer to the beam energy applied to a small region of the sample during milling. The dose can be controlled with parameters of the beam and the beam pattern as applied to the sample during milling, including the beam energy, the dwell time of the beam at a location, the scan speed of the beam as it moves in the pattern. By milling the sample with a non-uniform dose, variations in the beam pattern across the cutface due to the state of the beam system can be minimized. As used herein, the terms “non-uniform dose” and “variable dose” may be used interchangeably to describe a dose applied to the sample having different values depending on the location of the ion beam when directed toward the sample.

Milling a lamella to a very small thickness (e.g., <15 nm) can result in warping or bending across the lamella's length, transverse to the direction of milling. Such warping can cause portions of the lamella cutface to be closer or further to the beam axis of the FIB, causing over and/or under milling of the sample that can lead to the sample not being suitable for use in imaging. To avoid this warping, a thick frame of sample material can be left surrounding the ROI to provide structural stability for the lamella. The non-uniform dose techniques can allow for the thick frame of surrounding material to remain while thinning the ROI, resulting in lamellae that have very thin ROIs exhibiting a high degree of parallelism over a large height of the ROI.

By using non-uniform ion beam dose when milling a sample, numerous advantages are obtained over conventional sample preparation techniques. As discussed briefly above, the current state of the art vase-shaped process is highly sensitive to the state of the ion beam system, limiting sample-to-sample repeatability when preparing lamellae and preventing high-throughput for automated sample preparation, since manual adjustments need to be made to account for changes to the system state. By employing non-uniform dose techniques, the samples can first be thinned into a wedge-shaped profile, which is much less sensitive to the system state, and then thinned using a non-uniform dose pattern to achieve thin samples over a large ROI. Additionally, non-uniform dose milling can produce a sample exhibiting a high degree of parallelism between the cutfaces over a larger height of the ROI. For example, a sample prepared using non-uniform dose techniques may have a thickness that varies by less than 2 nm over an ROI height of 300 nm. By contrast, a sample prepared using the uniform dose vase process may exhibit a thickness that varies by 10 nm over an ROI height of 300 nm. Such parallelism in the sample can limit the over milling of structures in the ROI.

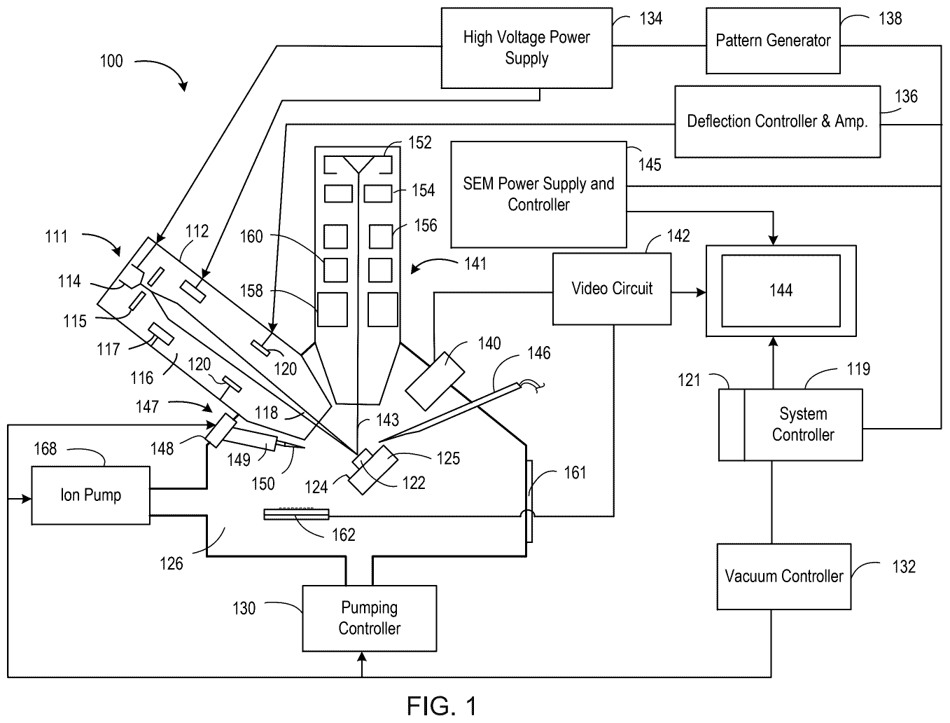

FIG. 1 is a schematic diagram of an example dual beam system 100 for preparing samples using non-uniform dose, according to some embodiments. System 100 may be used to implement the non-uniform ion beam dose techniques discussed herein. In some embodiments, the system 100 will perform sample milling with beam patterns configured to apply a non-uniform dose. However, in other embodiments, the milling algorithms may be performed by a computing system coupled to system 100, such as at a user's desk or a cloud based computing system. In either embodiment, the determination of the beam pattern and dose may be provided to system 100 for automatic milling control to ensure that the profile of the thinned lamella is correctly obtained. While an example of suitable hardware is provided below, the invention is not limited to being implemented in any particular type of hardware.

An SEM 141, along with power supply and control unit 145, is provided with the dual beam system 100. An electron beam 143 is emitted from a cathode 152 by applying voltage between cathode 152 and an anode 154. Electron beam 143 is focused to a fine spot by means of a condensing lens 156 and an objective lens 158. Electron beam 143 is scanned two-dimensionally on the specimen by means of a deflector 160. Operation of condensing lens 156, objective lens 158, and deflector 160 is controlled by power supply and control unit 145.

Electron beam 143 can be focused onto sample 122, which is on stage 125 within lower chamber 126. Substrate 122 may be located on a surface of stage 125 or on TEM sample holder 124, which extends from the surface of stage 125.

When the electrons in the electron beam strike sample 122, secondary electrons are emitted. These secondary electrons are detected by secondary electron detector 140. In some embodiments, STEM detector 162, located beneath the TEM sample holder 124 and the stage 125 collects electrons that are transmitted through the sample mounted on the TEM sample holder.

System 100 also includes FIB system 111 which comprises an evacuated chamber having an ion column 112 within which are located an ion source 114 and focusing components 116 including extractor electrodes and an electrostatic optical system. The axis of focusing column 116 may be tilted, 52 degrees for example, from the axis of the electron column 141. The ion column 112 includes an ion source 114, an extraction electrode 115, a focusing element 117, deflection elements 120, which operate in concert to form focused ion beam 118. Focused ion beam 118 passes from ion source 114 through focusing components 116 and between electrostatic deflection means schematically indicated at 120 toward sample 122, which may comprise, for example, a semiconductor wafer positioned on movable stage 125 within lower chamber 126. In some embodiments, a sample may be located on TEM grid holder 124, where the sample may be a chunk extracted from sample 122. The chunk may then undergo further processing with the FIB to form a final lamella of a desired thickness in accordance with techniques disclosed herein.

Stage 125 can move in a horizontal plane (X and Y axes) and vertically (Z axis). Stage 125 can also tilt and rotate about the Z axis. In some embodiments, a separate TEM sample stage 124 can be used. Such a TEM sample stage will also preferably be moveable in the X, Y, and Z axes as well as tiltable and rotatable. In some embodiments, the tilting of the stage 125/TEM holder 124 may be in and out of the plane of the ion beam 118, and the rotating of the stage is around the ion beam 118. As used herein to illustrate the disclosed techniques, such relationship will be maintained when discussing rotation and tilting of a sample. Of course, the opposite definitions could be used but would still fall within the contours of the present disclosure.

A door 161 is opened for inserting sample 122 onto stage 125. Depending on the tilt of the stage 124/125, the Z axis will be in the direction of the optical axis of the relevant column. For example, during a data gathering stage of the disclosed techniques, the Z axis will be in the direction, e.g., parallel with, the FIB optical axis as indicated by the ion beam 118. In such a coordinate system, the X and Y axis will be referenced from the Z-axis. For example, the X-axis may be in and out of the page showing FIG. 1, whereas the Y-axis will be in the page, all while all three axes maintain their perpendicular nature to one another.

An ion pump 168 is employed for evacuating the neck portion. The chamber 126 is evacuated with turbomolecular and mechanical pumping system 130 under the control of vacuum controller 132. The vacuum system provides within chamber 126 a vacuum of between approximately 1×10⁻⁷ Torr and 5×10⁻⁴ Torr. If an etch assisting, an etch retarding gas, or a deposition precursor gas is used, the chamber background pressure may rise, typically to about 1×10−⁻⁵ Torr.

The high voltage power supply provides an appropriate acceleration voltage to electrodes in focusing column 116 for energizing and focusing ion beam 118. When it strikes sample 122, material is sputtered, that is physically ejected, from the sample. Alternatively, ion beam 118 can decompose a precursor gas to deposit a material.

High voltage power supply 134 is connected to ion source 114 as well as to appropriate electrodes in ion beam focusing components 116 for forming an approximately 1 keV to 60 keV ion beam 118 and directing the same toward a sample. Deflection controller and amplifier 136, operated in accordance with a prescribed pattern provided by pattern generator 138, is coupled to deflection plates 120 whereby ion beam 118 may be controlled manually or automatically to trace out a corresponding pattern on the upper surface of sample 122. In some systems the deflection plates are placed before the final lens, as is well known in the art. Beam blanking electrodes (not shown) within ion beam focusing column 116 cause ion beam 118 to impact onto blanking aperture (not shown) instead of sample 122 when a blanking controller (not shown) applies a blanking voltage to the blanking electrode.

The ion source 114 typically provides an ion beam based on the type of ion source. In some embodiments, the ion source 114 is a liquid metal ion source that can provide a gallium ion beam, for example. In other embodiments, the ion source 114 may be plasma-type ion source that can deliver a number of different ion species, such as oxygen, xenon, and nitrogen, to name a few. The ion source 114 typically is capable of being focused into a sub one-tenth micrometer wide beam at sample 122 or TEM grid holder 124 for either modifying the sample 122 by ion milling, ion-induced etching, material deposition, or for the purpose of imaging the sample 122.

A charged particle detector 140, such as an Everhart-Thornley detector or multi-channel plate, used for detecting secondary ion or electron emission is connected to a video circuit 142 that supplies drive signals to video monitor 144 and receiving deflection signals from a system controller 119. The location of charged particle detector 140 within lower chamber 126 can vary in different embodiments. For example, a charged particle detector 140 can be coaxial with the ion beam and include a hole for allowing the ion beam to pass. In other embodiments, secondary particles can be collected through a final lens and then diverted off axis for collection.

A micromanipulator 147 can precisely move objects within the vacuum chamber. Micromanipulator 147 may comprise precision electric motors 148 positioned outside the vacuum chamber to provide X, Y, Z, and theta control of a portion 149 positioned within the vacuum chamber. The micromanipulator 147 can be fitted with different end effectors for manipulating small objects. In the embodiments described herein, the end effector is a thin probe 150.

A gas delivery system 146 extends into lower chamber 126 for introducing and directing a gaseous vapor toward sample 122. For example, iodine can be delivered to enhance etching, or a metal organic compound can be delivered to deposit a metal.

System controller 119 controls the operations of the various parts of dual beam system 100. Through system controller 119, a user can cause ion beam 118 or electron beam 143 to be scanned in a desired manner through commands entered into a conventional user interface (not shown). Alternatively, system controller 119 may control dual beam system 100 in accordance with programmed instructions stored in a memory 121. In some embodiments, dual beam system 100 incorporates image recognition software to automatically identify regions of interest, and then the system can manually or automatically extract samples in accordance with the invention. For example, the system could automatically locate similar features on semiconductor wafers including multiple devices, and take samples of those features on different (or the same) devices.

In operation in accordance with the techniques disclosed herein, system 100 images a working surface (e.g., a cutface) of a sample 122, the sample 122 being a chunk previously removed from a substrate. The chunk, which may be about 1 μm in thickness, may be attached to TEM holder 124 in this example. As used herein, the working surface is a side surface of the chunk, the chunk needing to be thinned into a final lamella thickness. The sample 122 may include structures that should be aligned/oriented to the ion beam 118, such as in terms of rotation and/or tilt, so that during the final lamella formation, structures that require subsequent imaging are not removed. The image of the newly exposed surface can be acquired using either the electron column 141 or the FIB 111.

Layers of sample 122 can be removed from the working surface. The removal of a layer may be performed using FIB milling or ion induced etching using a gas precursor. Layers can be removed in smaller “slices” according to certain embodiments, in which slices of about 1 nm to 5 nm are removed sequentially. After the slice is removed, the newly exposed surface is imaged. The process of image acquisition and slice removal may be repeated for 25, 50, 75, or 100 times, but any other number of slices are contemplated herein. The working surface of the lamella can show structures, such as lines of devices including FETs, which are desired to be imaged and/or analyzed.

The removal of a layer of material from the sample 122 can be done by directing the FIB 111 toward a portion of the sample 122 in a pattern. For example, the ion beam may raster over the surface of the sample 122 in the portion, removing the desired layer. As described in more detail below, the system controller 119 can be configured to direct the ion beam over a portion of the sample to vary the dose of the FIB 111 applied to any point in the portion of the sample. For example, the FIB 111 can raster more quickly at one portion of the surface of the sample 122, thereby having a lower dose since the FIB 111 may not deposit as much energy to the sample at each point in the raster. At another portion of the surface of the sample 122, the FIB 111 can raster more slowly, thereby having a higher dose in this portion. The variation in dose for the pattern may be linear or non-linear, depending on the desired characteristics of the FIB 111 during the milling process.

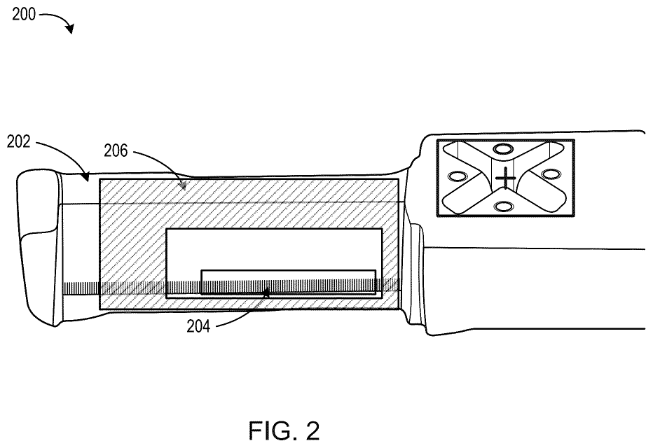

FIG. 2 is a diagram illustrating a view of a sample 200 for preparation showing a region of interest 204, according to some embodiments. The dual beam charged particle microscope system described above with respect to FIG. 1 can be used when preparing the sample 200.

The view shown in FIG. 2 depicts a face of the sample 200 after an initial formation technique, for example a cut and lift out technique. For example, the system 100 may be used to remove the sample 200 prior to milling the lamella 202 for subsequent imaging (e.g., via TEM). The portion of the sample 200 at the right includes a fiducial used to help guide the initial formation of the lamella 202. The material of the sample 200 near the fiducial is typically not of interest in the analysis and forms a structural component of the lamella 202 for handling in the dual beam charged particle microscope. For example, the sample 200 may be attached to TEM holder 124 of FIG. 1 via material to the right of the fiducial.

The lamella 202 can include the region of interest 204, depicted bounded by the inner rectangle shown in FIG. 2. The region of interest 204 can include a region where one or more structures are present in the lamella 202. For example, the region of interest 204 can include a portion of a device line including one or more semiconductor device structures. Because of the scale of the structures (e.g., nanometer scale structures for semiconductor devices), to obtain suitable images of the region of interest 204, the lamella 202 may be thinned to a thickness of less than about 12 nm. Thinning the lamella 202 can include removing material from the sample 200 at the face of the lamella 202 shown in FIG. 2. Additionally, material can be removed from the sample 200 at the face opposite the face shown in FIG. 2.

To provide structural resilience for the lamella 202 when the region of interest 204 is thinned to thicknesses of approximately 10 nm, a frame 206 of material of the sample 200 may remain thicker during the thinning process. The frame 206 is depicted in FIG. 2 by the shaded rectangular area. During the thinning process, material can be removed from the sample 200 for the portion of the sample 200 inside the frame 206, including the region of interest 204. The lamella 202 can be thinned via FIB milling. During thinning, an ion beam may be directed toward a portion of the lamella 202. The portion may include a region inside the frame 206 of the lamella 202. The ion beam can be directed toward the face of the lamella 202 in a pattern that corresponds to the area inside the frame 206. The dimensions and location of the frame 206 around the lamella 202 can be controlled by the configuration of the pattern used to thin the sample. For example, the ion beam may be configured to remove material in a raster pattern within the frame 206 area. As described below, the pattern for the ion beam may be configured to provide a variable dose to the face of the lamella 202 inside the frame 206, including the region of interest 204. By varying the dose, more material may be removed from the lamella 202 at the region of interest 204 than removed from the frame 206, leaving the portion of the sample 200 defined by the frame 206 thicker than the portion of the sample 200 inside the frame 206. In some embodiments, the direction of the thinning may be reversed depending on the type of sample 200 and the milling techniques employed (e.g., backside thinning).

Thinning of the lamella 202 can proceed in several steps in which a layer of material is removed at each step. For example, a first layer of material can be removed from the lamella 202 within the frame 206 shown in FIG. 2. Subsequently, a second layer (or third, or suitable number of additional layers) can be removed from an additional portion of the lamella 202. The energy of the ion beam can be different for the removal of each layer. For example, a first layer can be removed using a first energy of the ion beam (e.g., 30 kV) while a second layer can be removed using a second energy of the ion beam (e.g., 2 kV). In some embodiments, the dose of the ion beam may be uniform at the first energy (e.g., 30 kV) to remove the first layer and form a wedge shaped profile for the lamella 202. The dose of the ion beam may be non-uniform at the second energy (e.g., 2 kV) to remove the second layer from the lamella 202 to produce the thin region of interest 204 exhibiting a high degree of parallelism over the height of the region of interest 204. The wedge shape profile and the thin region of interest 204 may be supported and surrounded by the material of the thicker from 206.

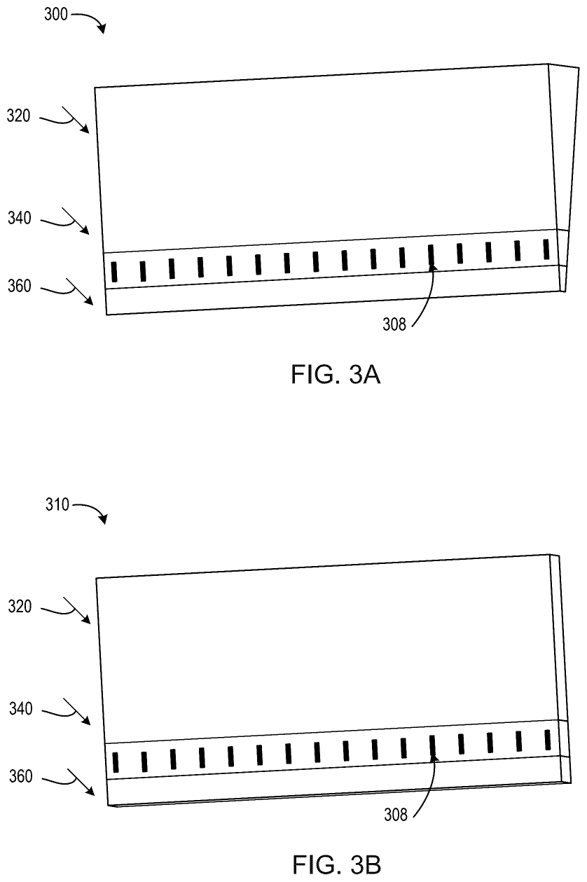

FIG. 3A is a diagram illustrating the profile a sample 300 first prepared with a uniform dose and subject to milling with a non-uniform dose, according to some embodiments. The thinning operations can be configured to reduce the thickness of the sample 300 to a desired thickness. The initial thickness of a lamella after cut and lift out can be on the order of 1 μm, while the length of the lamella may be about 3 μm or greater. The lamella can be thinned by removing layers of material until the thickness is about 100 nm. As depicted in FIG. 3A, the sample 300 may have a wedge-shaped profile after being formed by an initial stage of a thinning process. For example, an ion beam at 30 kV and with a uniform dose can be used to produce the wedge profile of the sample 300. The sample 300 may correspond to a portion of sample 200 described above with respect to FIG. 2. For example, sample 300 may be represent a portion of the lamella 202 within the frame 206 and including the region of interest 204.

After the wedge profile of the sample 300 is produced using the ion beam at a first energy, the sample 300 may be further thinned using the ion beam at a second energy and having a non-uniform dose. The ion beam can be directed toward the sample 300 so that the dose applied to the sample 300 varies depending on the location. For example, the ion beam can be configured to apply no dose to the sample 300 at a top portion 320 (indicated by the arrow), a high dose at a middle portion 340, and a low dose at a bottom portion 360. The high dose at the middle portion 340 may be higher than the low dose of the bottom portion 360. The sample 300 may include one or more structures 308. For example, the structures 308 may be part of a device line of one or more semiconductor devices in a region of interest of the sample 300. By varying the dose, the thinning process for the sample can achieve a thin and highly parallel lamella in the region of interest including the structures 308 by removing additional material in the portions of the wedge shaped profile that are thicker (e.g., the middle portion 340) due to the wedge profile. Within the sample 300, additional device lines may be formed parallel to the devices shown at the face of sample 300 but deeper within the sample volume. Thus, a device line with structures similar to structures 308 may be located behind the structures 308. As the lamella is thinned, the material of the structures 308 at the surface can be removed, revealing the devices and associated structures deeper within the sample 300. In addition, by applying no dose to the top portion 320, a thicker frame of material (not shown in FIGS. 3A and 3B, but may be similar to frame 206 of FIG. 2) may be maintained around the thinned portion of the sample 300, providing structural stability for the lamella as the thickness is reduced below 100 nm.

As described above, the dose of the ion beam can be the energy deposited by the ion beam at the location of the sample 300. The dose can be characterized by the energy of the ion beam and dwell time and/or scan speed of the ion beam for a pattern on the sample. For example, the ion beam may have a constant beam energy (e.g., 2 kV) and may be directed toward the sample 300 in the high dose middle portion 340 with a slower scan speed across the middle portion 340. As the ion beam reaches the low dose bottom portion 360, the scan speed may be increased, thereby reducing the dose applied to the sample 300 in the bottom portion 360. By reducing the dose, the amount of material removed from the sample in the bottom portion 360 may be less than the amount of material removed from the sample in the middle portion 340. For the no dose top portion 320, the ion beam may not be directed toward the sample 300 at that location, so that no or minimal material is removed from the top portion 320. Additionally or alternatively, the dose of the ion beam can be varied by modifying the dwell time of the ion beam at locations in the pattern and/or by increasing or decreasing the number of passes of the ion beam across a line of the pattern.

In some embodiments, the dose applied to the sample 300 can vary linearly from the high dose middle portion 340 to the low dose bottom portion 360. For example, for each line of the ion beam scan pattern, the scan speed of the ion beam across the surface of the sample can be increased, reducing the dose for each subsequent line in a linear manner. In other embodiments, the dose applied to the sample 300 can vary non-linearly. For example, the dose may increase quadratically for each line of the pattern. In some embodiments, the dose may be varied by changing the energy of the ion beam in conjunction with changing the scan speed, number of repeated passes of the beam across a scan line, and/or dwell time parameters.

In some embodiments, thinning the sample 300 using a non-uniform dose for the ion beam can occur for removing multiple layers from the sample 300. For example, the ion beam may be directed toward the surface of the sample at a first beam energy (e.g., 10 kV) using a non-uniform dose, with a high dose in the middle portion 340 and a low dose in the bottom portion 360. After a layer of material is removed from the sample, the ion beam may again be directed toward the surface of the sample at a second beam energy (e.g., 2 kV) using a non-uniform dose, again with a high dose in the middle portion 340 and a low dose in the bottom portion 360. In some embodiments, the variation in the dose can be different for the removal of different layers of the sample 300. For example, the non-uniform dose applied at the first beam energy may be linearly non-uniform, while the non-uniform dose applied at the second beam energy may be quadratically non-uniform.

FIG. 3B is a diagram illustrating a profile of a sample subject to milling with a non-uniform dose, according to some embodiments. As depicted in FIG. 3B and in contrast to the sample 300 shown in FIG. 3A, the sample 310 may have a planar or parallel structure after initial removal from a substrate or an initial thinning process (e.g., thinned by removing layers of material until the thickness is about 100 nm). The sample 310 may correspond to a portion of sample 200 described above with respect to FIG. 2. For example, sample 300 may be represent a portion of the lamella 202 within the frame 206 and including the region of interest 204. The embodiments and examples described above with respect to sample 300 of FIG. 3A apply equally to sample 310. For example, the ion beam can be configured to apply no dose to the sample 310 at a top portion 320, a high dose at a middle portion 340, and a low dose at a bottom portion 360.

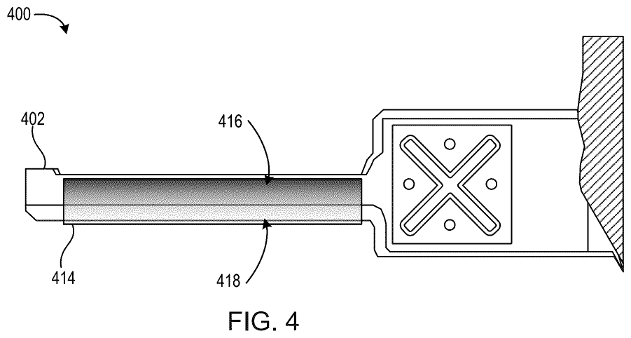

FIG. 4 is a diagram illustrating a view of a sample 400 subject to milling with a non-uniform dose, according to some embodiments. The sample 400 can include a lamella 402, which can be an example of lamella 202 described above with respect to FIG. 2.

When thinning the lamella 402 with a non-uniform dose, the ion beam can be directed toward the sample in a pattern 414. The pattern 414 can define the area of the lamella 402 to which the dose is applied. As depicted in FIG. 4, the pattern 414 can have a gradient corresponding to the dose of the ion beam. In a high dose region 416, the dose of the ion beam can be greater than dose of the ion beam in a low dose region 418. The dose of the ion beam can vary linearly from the high dose region 416 to the low dose region 418, as illustrated with the gradient of the pattern 414.

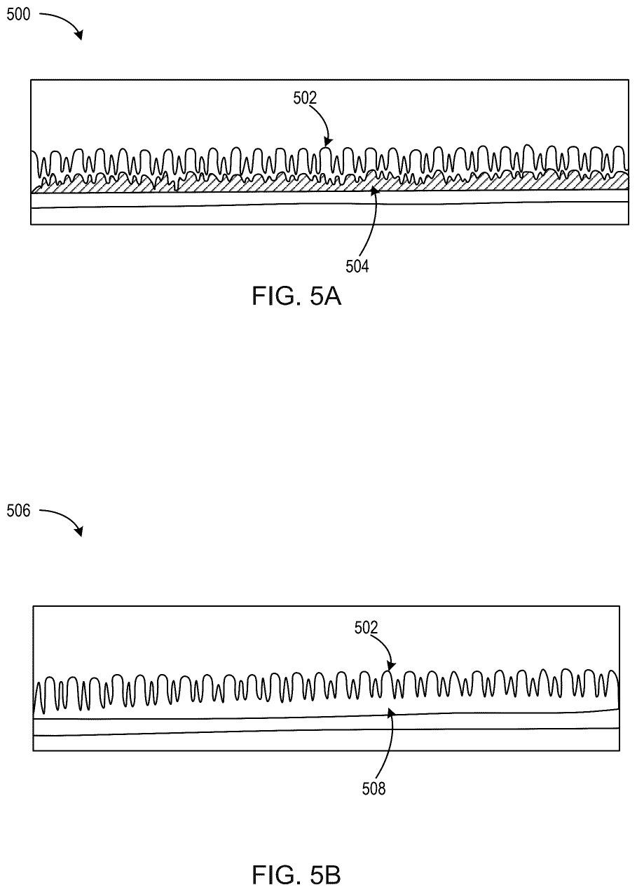

FIG. 5A is a diagram illustrating a view of a cutface 500 of a sample prepared with a uniform dose, according to some embodiments. The cutface 500 may correspond to a region of interest of the sample. For example, the cutface 500 can include one or more structures of a device line. The diagram of FIG. 5A may be similar to an image that can be obtained from a lamella using the electron beam of a dual beam charged particle microscope, for example the system 100 of FIG. 1. In some embodiments, the ion beam may be used for imaging the cutface 500. The lamella shown in FIG. 5A may have been thinned to relatively uniform thickness using a uniform dose. For example, the lamella may have been thinned using the vase-shaped profile described above.

As shown in FIG. 5A, the cutface 500 can include structures 502 of a device line. Shown below the structures 502 can be a wordline 504 of the device line. The wordline 504 may be the same or a different material (e.g., polysilicon) than the structures 502. When thinning a lamella using a uniform dose, material may be removed from the lamella so that the wordline 504 is exposed at the surface of the cutface 500 when the structures 502 are also present at the surface. A mark of parallelism in a lamella (e.g., the cutface 500 substantially parallel to the opposite face of the lamella) including structures like structures 502 can be the presence of the structures 502 (visible in the SEM imaging) without the wordline 504 also being visible. For example, the cutface 500 may exhibit less parallelism in the region of interest containing the structures 502 and wordline 504 due to the wordline 504 being visible, since too much material may be removed from the lamella below the structures 502.

When using an ion beam to thin a lamella, endpointing techniques can be used to control the depth of the milling process and the amount of material removed in each successive layer. Control of a FIB milling process can be achieved by imaging the surface of the sample during milling to identify structures (e.g., structures 502) of interest and then comparing the shape (e.g., dimensions like width, pitch/separation, absence of artifacts/occlusions, etc.) of the structures to the expected shape of the structures. When the imaged structures match the expected shape of the desired structures for the sample, the milling process can be stopped. Because the rounded “peaks” of the structures 502 may be the desired shape of the structures, a milling process using endpointing but with a uniform ion beam dose may stop with the cutface 500 appearing as in FIG. 5A, with too much material removed near the bottom and exposing wordline 504.

FIG. 5B is a diagram illustrating a view of a cutface 506 of a sample prepared with a non-uniform dose, according to some embodiments. The sample may be similar to the sample prepared as in FIG. 5A using the uniform dose, including have structures 502 in a region of interest of the sample.

By contrast with FIG. 5A, the cutface 506 of FIG. 5B can have the structures 502 visible with no wordline material visible in the region 508. As discussed above, the wordline 504 may be visible in cutface 500 due to excess material removed by the ion beam applied to the sample in a uniform dose. With a non-uniform dose, the ion beam may be applied to the sample so that there is a lower dose applied at the region 508 below the region containing the structures 502. Thus, when using the image of the cutface 506 for endpointing to control the thinning process of the sample, the process can be stopped with a lamella having a high degree of parallelism in the region of interest.

Although FIGS. 5A and 5B make reference to a wordline 504 of a semiconductor device (e.g., a buried-channel-array transistor), other semiconductor devices having different structures are contemplated.

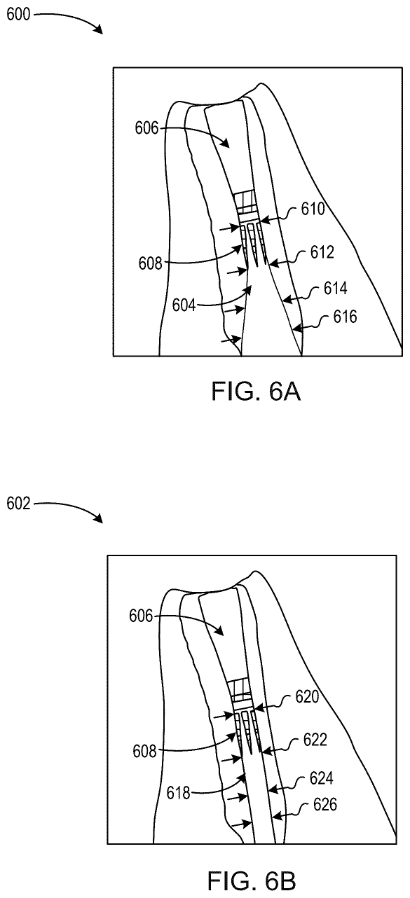

FIG. 6A is a diagram illustrating a profile view of a sample 600 prepared with a uniform dose, according to some embodiments. The sample 600 can be a lamella 604. The view shown in FIG. 6A can be from the side of the lamella 604 transverse to the direction of milling. The lamella 604 can have a protective layer 606 deposited at a portion of the sample “below” (above as oriented in FIG. 6A) structures 608. The structures 608 may be part of a device line. The structures 608 can be included in a region of interest (e.g., region of interest 204 of FIG. 2). The region of interest can have a “height” defined by dimension marks 610, 616. The height of the region of interest between dimension mark 610 and dimension mark 616 may, for example, be about 300 nm. The profile shown in FIG. 6A can correspond to the vase-shaped profile described above.

The thickness of the lamella 604 can vary over the height of the region of interest. For example, the thickness at dimension mark 610 may be about 10.9 nm, the thickness at dimension mark 612 may be about 13 nm, the thickness at dimension mark 614 may be about 17 nm, and the thickness at dimension mark 616 may be about 20 nm. The resulting variation in the thickness of the lamella 604 across the 300 nm height of the region of interest can therefore be about 10 nm.

FIG. 6B is a diagram illustrating a profile view of a sample 602 prepared with a non-uniform dose, according to some embodiments. The sample 602 can be a lamella 618 having structures 608 and a protective layer 606, similar to lamella 604. The lamella 618 can have a region of interest including the structures 608 and having a height defined by dimension marks 620, 626. The height of the region of interest between dimension mark 620 and dimension mark 626 may, for example, be about 300 nm.

As with lamella 604, the thickness of lamella 618 can vary over the height of the region of interest. For example, the thickness at dimension mark 620 may be about 71 nm, the thickness at dimension mark 622 may be about 71 nm, the thickness at dimension mark 624 may be about 72 nm, and the thickness at dimension mark 626 may be about 70 nm. The resulting variation in the thickness of the lamella 604 across the 300 nm height of the region of interest can therefore be about 2 nm. Although the values of the thickness of lamella 618 as depicted in FIG. 6B is greater than the values of the thickness of lamella 604 of FIG. 6A, the measurements provided above are meant to be exemplary of the variation in thickness over a large height of a region of interest. Removal of additional layers of the lamella 618 using a non-uniform dose can reduce the thickness of the lamella 618 to less than about 10 nm while maintaining similar variation of thickness over the height of the region of interest.

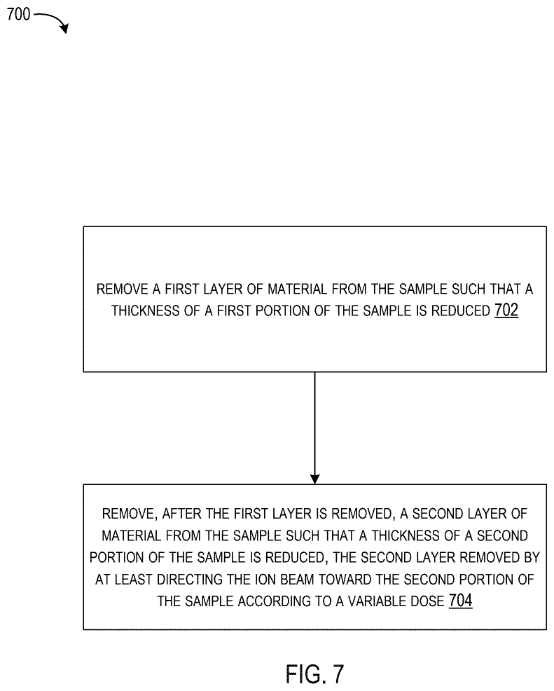

FIG. 7 is a flow diagram of an example process 700 for operating a dual beam charged particle microscope system to prepare a sample using a non-uniform dose, according to some embodiments. The dual beam charged particle microscope system may be an example of other charged particle microscope systems described herein, including system 100 of FIG. 1. The charged particle microscope system can include a computer system (e.g., system controller 119 of FIG. 1) configured to carry out the operations of process 700. For example, a computer system may be configured to adjust the parameters of the electron beam (e.g., accelerating potential, beam focus parameters, beam current, beam deflection, etc.), the ion beam (e.g., accelerating potential, beam focus parameters, ion species selection, beam current, etc.), the milling patterns (e.g., raster), the dose (e.g., dwell time, scan speed), the scanning/imaging parameters for SEM mode (e.g., sweep time, dwell time, etc.), activation/deactivation of both the electron beam and the ion beam (or additional beams, e.g., laser beams, present in multiple beam systems), detector settings (e.g., biasing voltage, collector grid voltage, etc.), and other suitable parameters for the operation of such a microscopy system. The sample may be an example of any of the samples described herein, including sample 200 of FIG. 2 and sample 602 of FIG. 6B.

The process 700 can begin at block 702, with removing a first layer of material from a sample by directing an ion beam toward the sample such that a thickness of the first portion of the sample is reduced. The ion beam can be characterized by a first energy. For example, after performing a cut and lift process to remove a lamella from a substrate material, the lamella can be thinned with an ion beam at an energy of 30 kV until the lamella has a thickness of about 100 nm. The first portion of the sample can include a region of interest (e.g., region of interest 204 of FIG. 2) and a frame region (e.g., frame 206 of FIG. 2). The beam path of the ion beam may be substantially parallel to the cutface.

At block 704, after the first layer is removed from the sample, a second layer of material can be removed from the sample by at least direction the ion beam toward a second portion of the sample. Removing the second layer of material can reduce the thickness of the second portion of the sample. The ion beam can be directed toward the second portion of the sample according to a variable (non-uniform) dose. For example, the ion beam may be directed toward the second portion of the sample in a raster pattern, with the ion beam swept across the surface in successive lines. The scan speed of the ion beam across each line in the raster can characterize the dose received by the sample in that line. By increasing the scan speed, the dose can be reduced, creating a variable dose for each successive line in the pattern. The second portion of the sample can include the region of interest. The ion beam can be characterized by a second energy (e.g., 2 kV).

In several embodiments, the variable dose can be achieved by modifying one or more parameters of the ion beam. For example, as discussed above, the scan speed of the ion beam across the portion of the sample can be increased or decreased to adjust the dose. In another example, the ion beam may be swept across a line of the pattern two, three, or more, or a predetermined number of times, thereby increasing the dose relative to other lines of the pattern. For instance, a first line of the pattern may have N sweeps of the ion beam, the second line of the pattern can have N-1 sweeps of the ion beam, so that the dose for each line decreases linearly for successive lines in the pattern. As another example, the dwell time for the ion beam at a position in the pattern can be increased or decreased to increase or decrease the dose for the position. As a further example, the angle between the ion beam and the sample (e.g., the cutface of the sample) can be varied for one or more positions in the pattern. For instance, in a raster pattern, the beam angle can be larger (e.g., the beam axis more normal to the sample surface) for a first line in the pattern. The beam angle can then be reduced for successive lines in the raster pattern. In addition to raster patterns, other patterns like vector patterns are possible.

In some embodiments, the variable dose can vary linearly across the second portion of the sample. For example, for each successive line of a raster pattern, the dose can decrease linearly. In some embodiments, the variable dose can vary non-linearly across the second portion of the sample. For instance, the dose can vary quadratically, exponentially, or any suitable non-linear variation. In some embodiments, the variation in the dose can be aligned with a direction parallel to the cutface of the sample (e.g., the “height” of a lamella) as depicted in FIGS. 3 and 4.

In some embodiments, the sample can be rotated to position a surface opposite the second portion accessible to the axis of the ion beam. The ion beam can be directed toward the sample at the surface to remove a third layer of material, thereby further reducing the thickness of the second portion of the sample. The ion beam may maintain the second energy when performing the backside milling. The ion beam may also repeat the variable dose to mill the surface on the opposite side. For example, after removing the second layer of material from the cutface using a raster pattern with a linearly decreasing dose for successive lines in the raster pattern, the sample can be rotated in the sample chamber and the third layer of material removed from the opposite using the same raster pattern with the same linearly decreasing dose.

In some embodiments, the thickness of the second portion is characterized by a uniform thickness across the region of interest. The uniform thickness can have a variation of less than about 2 nm over 300 nm of height of the region of interest.

In some embodiments, removing the second layer of material can be stopped based at least in part on comparing an image of the region of interest to an endpoint. For example, an SEM image can be obtained for the cutface of the sample, showing one or more desired structures (e.g., structures 502 of FIG. 5). The desired structure can be an ideal device feature (e.g., gate fin of a FET) for a particular manufacturing specification of the devices in the sample. The desired structure can then include dimensions, profile, pitch, or other suitable parameters for comparison in image analysis. In some embodiments, comparing the image to the endpoint can include comparing the view of the first structure to the desired structure of the endpoint. If the parameter(s) (e.g., dimensions, profile, pitch, etc.) match (e.g., are equal within some desired tolerance), then the ion beam can be stopped for the first segment.

In some embodiments, the ion beam can be set to different energies for each layer removed. For example, the first layer can be removed with the ion beam set to a first energy (e.g., 30 kV) and the second layer can be removed using the N segments with the ion beam set to a second energy (e.g., 2 kV) different from the first energy.

In the preceding description, various embodiments have been described. For purposes of explanation, specific configurations and details have been set forth in order to provide a thorough understanding of the embodiments. However, it will also be apparent to one skilled in the art that the embodiments may be practiced without the specific details. Furthermore, well-known features may have been omitted or simplified in order not to obscure the embodiment being described. While example embodiments described herein center on dual beam (e.g., electron and ion beams) microscopy systems, these are meant as non-limiting, illustrative embodiments. Embodiments of the present disclosure are not limited to such materials, but rather are intended to address charged particle beam systems for which a wide array of particles can be applied to imaging, microanalysis, and/or processing of materials on an atomic scale. Such particles may include, but are not limited to, electrons, ions, or photons in TEM systems, SEM systems, STEM systems, ion beam systems, and/or particle accelerator systems.

Some embodiments of the present disclosure include a system including one or more data processors and/or logic circuits. In some embodiments, the system includes a non-transitory computer readable storage medium containing instructions (e.g., executable instructions, one or more computer programs, or one or more applications) which, when executed on the one or more data processors, cause the one or more data processors to perform part or all of one or more methods and/or part or all of one or more processes and workflows disclosed herein. Some embodiments of the present disclosure include a computer-program product tangibly embodied in a non-transitory machine-readable storage medium, for example, in the form of a computer program including a plurality of instructions executable by one or more processors. The instructions can be configured to cause one or more data processors to perform part or all of one or more methods and/or part or all of one or more processes disclosed herein, including, for example, process 700 of FIG. 7.

The terms and expressions which have been employed are used as terms of description and not of limitation, and there is no intention in the use of such terms and expressions of excluding any equivalents of the features shown and described or portions thereof, but it is recognized that various modifications are possible within the scope of the claims. Thus, it should be understood that although the present disclosure includes specific embodiments and optional features, modification and variation of the concepts herein disclosed may be resorted to by those skilled in the art, and that such modifications and variations are considered to be within the scope of the appended claims.

Where terms are used without explicit definition, it is understood that the ordinary meaning of the word is intended, unless a term carries a special and/or specific meaning in the field of charged particle microscopy systems or other relevant fields. The terms “about” or “substantially” are used to indicate a deviation from the stated property or numerical value within which the deviation has little to no influence of the corresponding function, property, or attribute of the structure being described. In an illustrated example, where a dimensional parameter is described as “substantially equal” to another dimensional parameter, the term “substantially” is intended to reflect that the two dimensions being compared can be unequal within a tolerable limit, such as a fabrication tolerance. Similarly, where a geometric parameter, such as an alignment or angular orientation, is described as “about” normal, “substantially” normal, or “substantially” parallel, the terms “about” or “substantially” are intended to reflect that the alignment or angular orientation can be different from the exact stated condition (e.g., not exactly normal) within a tolerable limit. For dimensional values, such as diameters, lengths, widths, or the like, the term “about” can be understood to describe a deviation from the stated value of up to ±10%. For example, a dimension of “about 10 nm” can describe a dimension from 9.9 nm to 10.1 nm.

The description provides exemplary embodiments, and is not intended to limit the scope, applicability or configuration of the disclosure. Rather, the ensuing description of the exemplary embodiments will provide those skilled in the art with an enabling description for implementing various embodiments. It is understood that various changes may be made in the function and arrangement of elements without departing from the spirit and scope as set forth in the appended claims.

Specific details are given in the description to provide a thorough understanding of the embodiments. However, it will be understood that the embodiments may be practiced without these specific details. For example, specific system components, systems, processes, and other elements of the present disclosure may be shown in schematic diagram form or omitted from illustrations in order not to obscure the embodiments in unnecessary detail. In other instances, well-known circuits, processes, components, structures, and/or techniques may be shown without unnecessary detail.

What is claimed is:

1. A system comprising:
a vacuum chamber;
a sample stage disposed in the vacuum chamber and configured to receive a sample in the vacuum chamber;
an ion beam column configured to provide an ion beam into the vacuum chamber; and
a controller comprising one or more processors and one or more memories storing computer-executable instructions that, when executed by the one or more processors, cause the system to:
remove a first layer of material from the sample such that a thickness of a first portion of the sample is reduced, the first layer removed by at least directing the ion beam toward the first portion of the sample; and
remove, after the first layer is removed, a second layer of material from the sample such that a thickness of a second portion of the sample is reduced, the second portion included in the first portion, the second layer removed by at least directing the ion beam toward the second portion of the sample according to a variable dose.

2. The system of claim 1, wherein removing the second layer of material from the sample comprises directing the ion beam in a pattern, and wherein the variable dose comprises repeating a sweep of the ion beam across the second portion for one or more lines of the pattern a predetermined number of times.

3. The system of claim 1, wherein removing the second layer of material from the sample comprises directing the ion beam in a pattern, and wherein the variable dose comprises a variable dwell time of the ion beam at one or more positions of the pattern.

4. The system of claim 1, wherein removing the second layer of material from the sample comprises directing the ion beam in a pattern, and wherein the variable dose comprises a variable angle between the ion beam and the sample at one or more positions of the pattern.

5. The system of claim 1, wherein removing the first layer of material comprises directing the ion beam toward the first portion at a first energy, wherein the second portion comprises a region of interest, and wherein removing the second layer of material comprises directing the ion beam toward the second portion at a second energy less than the first energy according to the variable dose.

6. The system of claim 5, wherein the first energy is about 30 kV.

7. The system of claim 5, wherein the second energy is about 2 kV.

8. The system of claim 1, wherein the one or more memories store additional computer-executable instructions that, when executed by the one or more processors of the controller, cause the system to further:
rotate the sample stage to position a surface opposite the second portion of the sample in a path of the ion beam;
remove a third layer of material from the sample such that the thickness of the second portion of the sample is further reduced, the third layer removed by at least directing the ion beam toward the surface opposite the second portion, the ion beam directed toward the surface according to the variable dose.

9. The system of claim 1, wherein the thickness of the second portion is characterized by a uniform thickness across a region of interest, the uniform thickness having a variation of less than about 2 nm over 300 nm of height of the region of interest.

10. The system of claim 1, wherein removing the second layer of material is stopped based at least in part on comparing an image of a region of interest to an endpoint.

11. A non-transitory computer-readable medium storing instructions that, comprising instructions that, when executed by a processor of a charged particle microscopy system, cause the charged particle microscopy system to:
remove a first layer of material from a sample such that a thickness of a first portion of the sample is reduced, the first layer removed by at least directing an ion beam toward the first portion of the sample; and
remove, after the first layer is removed, a second layer of material from the sample such that a thickness of a second portion of the sample is reduced, the second portion included in the first portion, the second layer removed by at least directing the ion beam toward the second portion of the sample according to a variable dose.

12. The non-transitory computer-readable medium of claim 11, removing the second layer of material from the sample comprises directing the ion beam in a pattern, and wherein the variable dose comprises repeating a sweep of the ion beam across the second portion for one or more lines of the pattern a predetermined number of times.

13. The non-transitory computer-readable medium of claim 11, wherein directing the ion beam toward the second portion of the sample comprises directing the ion beam in a pattern, and wherein the variable dose comprises a variable dwell time of the ion beam at one or more positions of the pattern.

14. The non-transitory computer-readable medium of claim 11, wherein removing the second layer of material from the sample comprises directing the ion beam in a pattern, and wherein the variable dose comprises a variable angle between the ion beam and the sample at one or more positions of the pattern.

15. The non-transitory computer-readable medium of claim 11, wherein the variable dose varies linearly across the second portion of the sample.

16. The non-transitory computer-readable medium of claim 11, wherein the variable dose varies non-linearly across the second portion of the sample.

17. A method, comprising:
thinning a sample to a thickness by at least using an ion beam to remove a layer of material from a surface of the sample, the ion beam configured to apply a variable dose to at least a portion of the surface of the sample.

18. The method of claim 17, wherein directing the ion beam toward at least the portion of the sample comprises directing the ion beam in a pattern, and wherein the variable dose comprises repeating a sweep of the ion beam across the portion for one or more lines of the pattern a predetermined number of times.

19. The method of claim 17, wherein the variable dose varies linearly across the portion of the sample.

20. The method of claim 17, wherein directing the ion beam toward the portion of the surface of the sample comprises directing the ion beam in a pattern, and wherein the variable dose comprises a variable dwell time of the ion beam at one or more positions of the pattern.
